(19) United States
(12) Patent Application Publication
(10) Pub. No.: US 2015/0296630 A1
(43) Pub. Date: Oct. 15, 2015

(54) BALL GRID ARRAY MOUNTING SYSTEM

(71) Applicant: Summit Imaging, Inc., Woodinville, WA (US)

(72) Inventor: Stephenjon Besagar Barredo, Lynnwood, WA (US)

(21) Appl. No.: 14/748,859

(22) Filed: Jun. 24, 2015

Related U.S. Application Data
(63) Continuation of application No. 14/197,911, filed on Mar. 5, 2014, now abandoned.
(60) Provisional application No. 61/772,915, filed on Mar. 5, 2013.

(51) Int. Cl. H05K 3/34; H05K 1/03; H05K 1/18; H01L 23/00; H01L 23/498

(52) U.S. Cl. CPC H05K 3/3436; H01L 24/17; H01L 23/49816; H01L 23/49838; H01L 23/49866; H05K 1/181; H05K 1/0313; H05K 1/0393; H05K 2203/041; H05K 2201/0154; H05K 2203/043

(57) ABSTRACT

A device for providing a reliable and robust electrical connection of a chip to a board using a plurality of solder balls, the device including a non-rigid body formed of a thermal resistant material having a top side and a bottom side, the bottom side having an adhesive layer; and an array of openings formed in the body, the array of openings arranged in a pattern that matches a pattern of conductive pads on the board, each opening having a circular plan form shape that is sized to enable a single solder ball to be slideably received in the opening, each opening spaced from adjacent openings by a distance that prevents adjacent solder balls from electrically connecting to each other when the solder balls are subjected to a temperature sufficient to reflow the solder ball.

### BACKGROUND

1. Technical Field

The present disclosure is directed to the electrical coupling of two circuit boards in back-to-back configuration and, more particularly, to a ball grid array reballing template and method of making and using.

2. Description of the Related Art

In an effort to reliably connect integrated circuits or “chips” to printed circuit boards, manufacturers have resorted to a variety of methods, including wire bonding, chip carriers with beam leads, and direct chip connections. Some manufacturers have experimented with soldering as one form of direct chip connection, but the results were less than favorable due to solder bridging and variations created in the spacing between the chip and the substrate.

One early method of direct chip connection involved the use of a copper micro-ball in which copper spheres were bonded to pads of the solid state device, such as a transistor, using, for example, solder. This resulted in the first arrangement of balls in a grid pattern, known now as the Ball Grid Array (BGA). As Surface Mount Technology (SMT) became more available with the BGA connection, other problems began to arise. Thermal expansion of the substrate sometimes caused a mismatch between the silicon device and the substrate, causing high stress in the structure and resulting low reliability. While the use of underfill and new materials addressed this problem, the move to solder balls in more densely arranged arrays increased the occurrence of solder bridging.

The solder “bump” or ball serves as the interconnection point between a device and a board in what is sometimes known as flip chip technology. In order for the solder joints to be formed, the solder ball must be constructed of fully reflowable material, such as eutectic Sn/Pb material, which enables a well-controlled process to provide bump heights with a standard deviation, typically less than 2.5 μm.

Referring initially to FIG. 1, shown therein is a cross-sectional view of a portion of a BGA arrangement 10 in which a solder ball 12 is mounted on a silicon substrate 14 via an aluminum pad 16. Typically, under bump metal 18 is formed on the pad 16 and sized and shaped to accommodate the solder ball 12. Other layers present on the silicon can include a nitride layer 20 and a benzocyclobutene layer 22.

In high density BGA applications, the close proximity of the solder balls can result in bridging when the solder ball expands outward during the reflow process. Another potential issue is “solder balling,” in which very small spherical particles of solder separate from the main body of the solder ball and form a bridge or joint between adjacent solder balls. This is a primary concern inasmuch as the artificial bridge between two adjacent leads can create functional problems in the associated electrical circuit.

Typical approaches to dealing with this problem include: (1) Selecting a reflow process that best fits the components used in the BGA array, including the paste used for the balls to hold them to the pad; and (2) minimizing solder paste exposure to high temperatures and humidities whenever possible. Of course, many electric circuits are used in high temperature and high humidity environments, which can result in solder bridging. Moreover, solder bridging can occur during the initial manufacturing process or during a repair or replacement operation in which components that have been separated are reattached.

Hence, there is a need for a new approach that offers a robust and functional interconnect solution in which the integrity of the connection is preserved, especially in the miniaturization and high density BGA environment, and that preserves the high performance operation of the circuit in all temperature and humidity environments.

### BRIEF SUMMARY

In accordance with the present disclosure, a device is provided for achieving a reliable and robust electrical connection between a ball grid array assembly to a printed circuit board, the ball grid array assembly having a plurality of conductive pads arranged in a pattern on a bottom side, and the printed circuit board having a plurality of conductive pads arranged in a mirror of the pattern on the bottom side of the ball grid array assembly. The device includes a non-rigid body formed of a thermal resistant material having a top side and a bottom side, the bottom side having an adhesive layer. An array of openings are formed in the body, the array of openings arranged in a pattern that matches the pattern of the conductive pads on the ball grid array assembly, each opening having a circular plan form shape that is sized to enable a single solder ball to be slideably received in the opening. Each opening is spaced from adjacent openings by a distance that prevents adjacent solder balls from electrically connecting to each other when subjected to a temperature sufficient to reflow the solder balls.

In accordance with a further aspect of the present disclosure, the non-rigid body is formed of a flexible, compliant material having a thickness in the range of 0.001 inches to 0.005 inches. More preferably the thickness is in the range of 0.1 mm to 0.9 mm.

In accordance with another aspect of the present disclosure, a method for reballing and attaching a ball grid array assembly is provided. The method includes forming a pattern on a template, the pattern reflecting the footprint of the ball grid array assembly that indicates at least a size of a solder ball and the locations for solder balls on the bottom side of the ball grid array assembly. The method also includes creating a plurality of apertures on the template coincident with the locations for the solder balls on the bottom side of the ball grid array assembly, affixing the template to the bottom side of the ball grid array assembly with the apertures in the template aligned with the locations for the solder balls on the ball grid array assembly. The method further includes applying solder paste to the locations for the solder balls on the ball grid array assembly, adhering a plurality of solder balls on the locations for the solder balls, placing the reballed ball grid array assembly onto a printed circuit board with the solder balls aligned with a plurality of pads on the printed circuit board, and reflowing the printed circuit board together with the reballed ball grid array assembly.

In accordance with another aspect of the present disclosure, an apparatus is provided that includes a first board having a plurality of conductive pads arranged in a pattern, a template comprising a non-rigid body having a top side and a bottom side, the bottom side having an adhesive layer and an array of openings in the body, the array of openings arranged in a pattern that is coincident with the pattern of conductive pads on the first board, each opening having a circular plan form shape, each opening spaced from adjacent openings by a distance. The template is mounted on the first board by adhering the adhesive layer to the first board and each opening in the array of openings in the body aligned with a respective conductive pad on the first board. The apparatus also includes a solder ball slideably received in each opening in the template to extend past the bottom side of the template to contact the respective pad on the first board and to extend above the top side of the body of the template, the solder ball electrically coupled to the respective pad on the first board and electrically insulated from adjacent solder balls by the template body.

In accordance with a further aspect of the present disclosure, the apparatus may further include a second board having a plurality of conductive pads formed therein and arranged in a pattern that is a mirror image of the pattern formed on the first board and the pattern of the array of openings formed in the template, the respective pads of the second board electrically coupled to a respective solder ball on the first board.

In accordance with yet another aspect of the present disclosure, the template is configured to have a thickness that prevents each solder ball from flowing into adjacent solder balls when reflowed for attachment to the first and second boards. Ideally, the adhesive may be formed of a material that allows the template to be removably adhered to the first board. Preferably, the solder ball is formed to reflow and electrically bond to the respective pad on the first and second boards when subjected to a thermal flow process.

### BRIEF DESCRIPTION OF THE SEVERAL VIEWS OF THE DRAWINGS

The foregoing and other features and advantages of the present disclosure will be more readily appreciated as the same become better understood from the following detailed description when taken in conjunction with the accompanying drawings, wherein:

FIG. 1 is a side view of a portion of a ball grid arrangement on a silicon substrate.

FIG. 2 is an exemplary side view of a deballed ball grid array assembly with a mounted template according to one embodiment of the present disclosure.

FIG. 3 is a simplified bottom view of the deballed ball grid array assembly in FIG. 2.

FIG. 4 is a side view of a reballed ball grid array assembly mounted onto a printed circuit board.

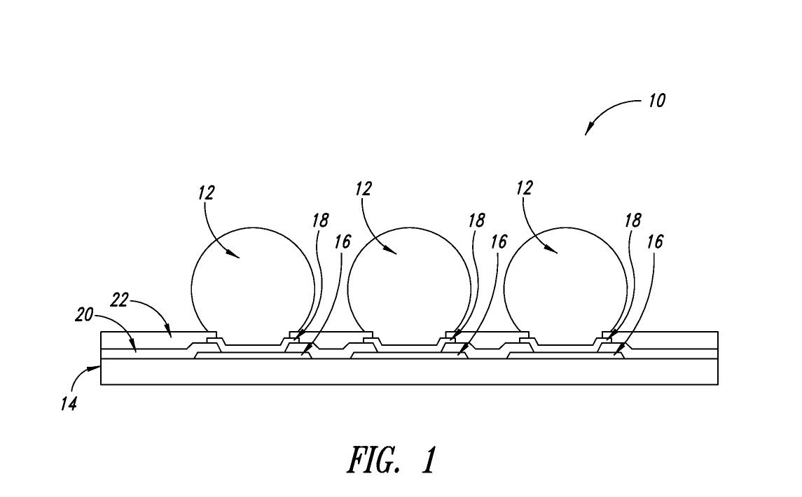

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known structures or components or both associated with ball grid array mounting systems and methods, including but not limited to the apparatus for reflowing the solder balls, have not been shown or described in order to avoid unnecessarily obscuring descriptions of the embodiments.

Unless the context requires otherwise, throughout the specification and claims that follow, the word “comprise” and variations thereof, such as “comprises” and “comprising” are to be construed in an open inclusive sense, that is, as “including, but not limited to.” The foregoing applies equally to the words “including” and “having.”

Reference throughout this description to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

FIG. 2 shows a simplified side view of a deballed ball grid array assembly 24 onto which one embodiment of a template from the present disclosure is mounted. The ball grid array assembly 24 in FIG. 2 includes an integrated circuit 26, a protective mold 34, a carrier board 30, pads 32, and a template 36 having an adhesive layer 28. The carrier board 30 maybe an organic substrate. The adhesive layer 28 of the template 36 is shown in FIG. 2 as being one side of the template 36 and affixed to the carrier board 30. In FIG. 2, the ball grid array 24 is deballed, no solder ball is shown, and the pads 32 are locations for receiving the solder balls.

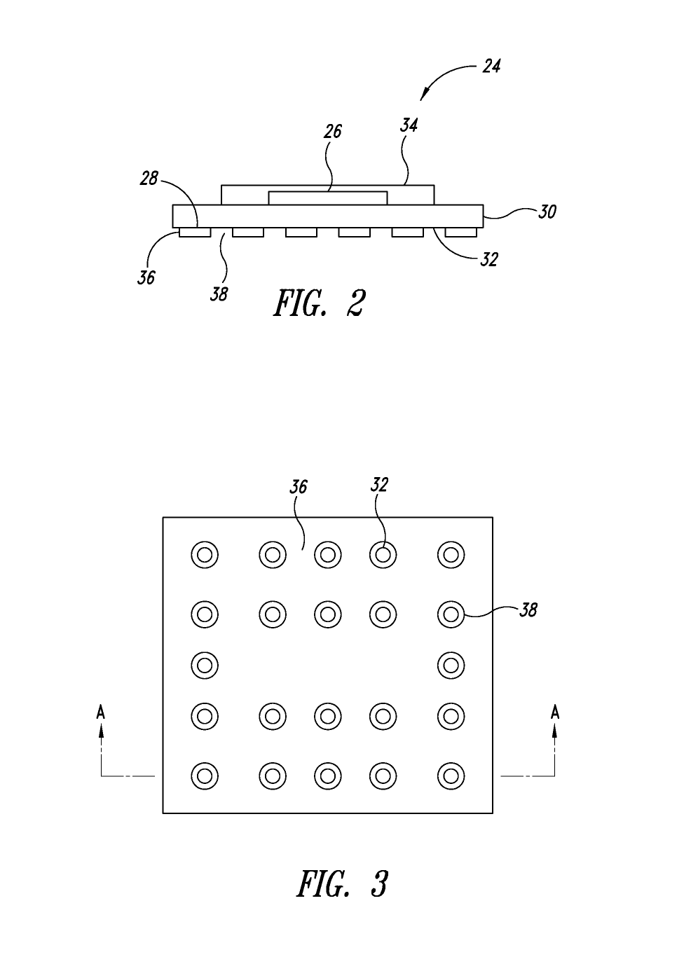

In FIG. 3, the deballed ball grid array assembly 24 with the mounted template 36 is viewed from the bottom side of the carrier board 30. The template 36 is a thermal resistant material with a top side and a bottom side, the bottom side having the adhesive layer 28 (not visible as viewed in FIG. 3) affixed to the carrier board 30. In a preferred embodiment, the material is a polyimide film such as Kapton Tape. To create the template 36, a pattern matching the footprint of the ball grid array assembly 24 is formed on the thermal resistant material, and apertures 38 are created coinciding with the pads 32 located on the carrier board 30. Each aperture 38 has a diameter sufficiently large to allow a solder ball to slide through and rest on the pad 32. The bottom side of the template 36 with its adhesive layer 28 is then affixed to the carrier board 30 of the ball grid array assembly 24. In FIG. 3, the pads 32 on the carrier board 30 are visible through the apertures 38 of the template 36. The apertures 38 are preferably sized to allow the balls to slide completely therethrough. However, in accordance with another aspect of the present disclosure, the apertures 38 can have a tight fit or interference fit that holds the balls in place in the apertures 38. This could require force to urge the ball in place, which could deform the ball and hence is not the preferred method.

Working with the bottom of the ball grid array assembly 24 facing up, the exposed pads 32 are coated with solder paste to prepare them to receive solder balls. In a preferred embodiment, a metal cut-out (not shown) is used to place the plurality of solder balls onto the pads 32. The metal cut-out has a plurality of apertures, and when placed over the bottom of the ball grid array assembly 30, the plurality of apertures coincide with pads 32 on the bottom of the ball grid array assembly 30, each aperture having a diameter sufficient to slidably receive one solder ball therethrough. A plurality of solder balls are poured over the surface of the metal cut-out and a subset of the plurality of solder balls slide through the apertures 38 of the template 36 and onto the pads 32. Residual solder balls are removed from the surface of the metal cut-out.

The ball grid array assembly 24 then undergoes a reflow process with an appropriate thermal profile to secure the solder balls onto the ball grid array assembly 24. In a preferred embodiment, the ball grid array assembly 24 undergoes the reflow process with the metal cut-out in place to help the solder balls on the pads 32 remain in place. The template 36 acts as a barrier between adjacent solder balls on the pads 32 on the carrier board 30 during the reflow process, preventing shorts due to bridging between melting solder balls. Once the solder balls are secured, the ball grid array assembly 24 is considered reballed.

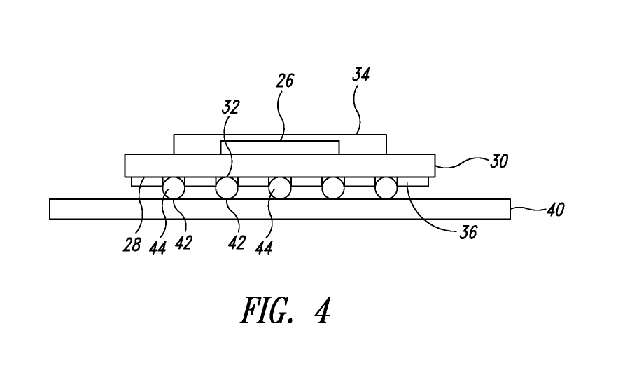

The reballed ball grid array assembly 24 can now be assembled onto a printed circuit board. FIG. 4 shows the reballed ball grid array assembly 24 soldered on the printed circuit board 40. The printed circuit board 40 has a plurality of pads 42 onto which the solder balls 44 of the ball grid array assembly 24 are soldered. The template 36 also may act as a barrier here between melting adjacent solder balls. The template 36 to may also be made thick enough to act as a spacer or support between the carrier board 30 and the printed circuit board 40, thus preventing the solder balls from ‘pancaking’ or becoming overly flattened during reflow to the point that adjacent solder balls touch each other and cause unwanted electrical shorts.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device for providing a reliable and robust electrical connection of a ball grid array assembly to a board using a plurality of solder balls, the ball grid array assembly having a plurality of conductive pads arranged in a pattern, the board also having a plurality of conductive pads arranged in a pattern that is a mirror of the pattern on the board, the device comprising:
a non-rigid body comprising a thermal resistant material having a top side and a bottom side, the bottom side having an adhesive layer; and
an array of openings in the body, the array of openings arranged in a pattern that matches the pattern of the conductive pads on the ball grid array assembly, each opening having a circular plan form shape that is sized to enable a single solder ball to be slideably received in the opening, each opening spaced from adjacent openings by a distance that prevents adjacent solder balls from electrically connecting to each other when the solder balls are subjected to a temperature sufficient to reflow the solder ball.

2. The device of claim 1 wherein the non-rigid body is a flexible, compliant material having a thickness in the range of 0.1 mm to 0.9 mm.

3. The device of claim 1 wherein the non-rigid body is a polyimide film having silicon adhesive on the bottom side.

4. An apparatus, comprising:
a first board having a plurality of conductive pads arranged in a pattern;
a template having
a non-rigid body having a top side and a bottom side, the bottom side having an adhesive layer; and
an array of openings in the body, the array of openings arranged in a pattern that is coincident with the pattern of conductive pads on the first board, each opening having a circular plan form shape, each opening spaced from adjacent openings by a distance, the template being mounted on the first board with the adhesive material adhered to the first board and the openings in the array of openings in the body aligned with a respective conductive pad on the first board;
a solder ball slideably received on the first board, the solder ball electrically coupled to the respective pad on the first board and electrically insulated from adjacent solder balls by the template body, each solder ball spaced apart from adjacent solder balls by the distance on the template to prevent electrical contact between the adjacent solder balls when the solder balls are subjected to a temperature sufficient to reflow the solder ball.

5. The apparatus of claim 4, further comprising a second board having a plurality of conductive pads formed therein and arranged in a pattern that is a mirror image of the pattern formed on the first board, the respective pads of the second board electrically coupled to a respective solder ball on the first board.

6. The apparatus of claim 4 wherein the template is formed of a dielectric material and configured to have a thickness that retains each solder ball in position on the respective conductive pad and holds the solder ball in its original shape when the solder ball is reflowed for attachment to the first and second boards.

7. The apparatus of claim 4 wherein the adhesive is formed of a material that allows the template to be removably adhered to the first board.

8. The apparatus of claim 4 wherein the solder ball is configured to reflow and electrically bond to the respective pad on the first and second boards when subjected to a thermal flow process.

9. An electronic apparatus, comprising:
a carrier board having first and second sides;
an integrated circuit structured to be mounted on a first side of the carrier board;
a plurality of conductive pads arranged in a pattern on the second side of the carrier board and structured to be electrically coupled to the integrated circuit ;
a template sized and shaped to be mounted on the second side of the carrier board, the template including:
a non-rigid body formed of electrically non-conductive material having a first side and a second side;
an adhesive layer on the second side of the body that is structured to adhere to the second side of the circuit board; and
a plurality of openings in the body arranged in a pattern that is structured to be coincident with the pattern of conductive pads on the carrier board, the template sized and shaped to be being mounted by the adhesive layer on the second side of the carrier board with each opening aligned with a respective conductive pad;
a plurality of solder balls, each solder ball sized and shaped to be received in a respective opening in the template body and to be electrically coupled to a respective pad on the circuit board while being electrically insulated from adjacent solder balls by the template body.

10. The electronic apparatus of claim 9, further comprising:
a printed circuit board having a first side;
a plurality of electrically conductive pads on the first side of the printed circuit board and arranged in a pattern that matches the pattern of conductive pads on the carrier boards;
the plurality of solder balls structured to be electrically coupled to the plurality of conductive pads on the printed circuit board to provide an electrically conductive path between the respective plurality of pads on the printed circuit board and the plurality of conductive pads on the second side of the carrier board; and
the template body having a thickness and each opening in the template body spaced apart from adjacent openings in the template body a distance that cooperates with the thickness of the template body to prevent electrical contact between adjacent solder balls positioned in the respective openings in the template body when the adjacent solder balls are subjected to a temperature sufficient to reflow the solder ball on to the respective plurality of electrically conductive pads on the printed circuit board.

11. The electronic apparatus of claim 9 wherein the template body has a thickness sufficient to act as a spacer or support between the carrier board and the printed circuit board while permitting electrical contact between the solder balls and the respective electrically conductive pads on the printed circuit board.

12. The electronic apparatus of claim 11 wherein the template body is formed of thermal resistant material.

13. An assembly, comprising:
a carrier board having an integrated circuit mounted thereon and a plurality of conductive pads electrically coupled to the integrated circuit;
a template mounted on the carrier board, the template having a plurality of apertures, each aperture positioned over a respective conductive pad;
a plurality of electrically conductive elements, each element received in a respective aperture of the template and electrically coupled to a respective conductive pad associated with the respective aperture.

14. The assembly of claim 13, further comprising a printed circuit board having a plurality of conductive pads, with a respective conductive pad electrically coupled to a respective electrically conductive element on the carrier board to form an electrically conductive path between the respective conductive pad on the printed circuit board and the integrated circuit on the carrier board.

15. The assembly of claim 14 wherein the electrically conductive elements comprise solder balls.

16. The assembly of claim 15 wherein the template is formed of electrically non-conductive thermal resistant material and has a thickness that prevents adjacent solder balls from becoming flattened or from flowing into adjacent solder balls during a reflow process.
